(19) United States
(12) Patent Application Publication
(10) Pub. No.: US 2018/0226261 A1
(43) Pub. Date: Aug. 9, 2018

(54) METHOD OF ANISOTROPICALLY ETCHING GRAPHENE

(71) Applicant: TOKYO ELECTRON LIMITED, Tokyo (JP)

(72) Inventors: Ryota IFUKU, Nirasaki City, Yamanashi (JP); Takashi MATSUMOTO, Nirasaki City, Yamanashi (JP)

(21) Appl. No.: 15/888,468

(22) Filed: Feb. 5, 2018

(30) Foreign Application Priority Data
Feb. 6, 2017 (JP) 2017-019827

(51) Int. Cl. H01L 21/3065; H01L 29/16; H01L 21/30; H01L 21/67; H01J 37/32

(52) U.S. Cl. CPC H01L 21/3065; H01L 29/1606; H01L 21/3003; H01J 37/32724; H01J 37/3222; H01J 2237/3345; H01L 21/67069

(57) ABSTRACT

A method for anisotropically etching graphene includes generating hydrogen plasma by microwave plasma, and anisotropically etching graphene by the generated hydrogen plasma.

### CROSS-REFERENCE TO RELATED APPLICATION

This application is based upon and claims the benefit of priority from Japanese Patent Application No. 2017-019827, filed on Feb. 6, 2017, the entire contents of which are incorporated herein by reference.

### TECHNICAL FIELD

The present disclosure relates to a method of anisotropically etching graphene.

### BACKGROUND

Graphene is constituted as an aggregate of six-membered ring structures by covalent bond (sp² bond) of carbon atoms and has the unique electronic, thermal and mechanical properties derived from a six-membered ring structure composed of carbon covalent bonds, such as mobility of 200,000 cm²/Vs or more, which is 100 times or more as great as that of silicon (Si), current density of 109 A/cm², which is 100 times or more as great as that of Cu, thermal conductivity higher than diamond, high fracture strength, largest Young's modulus, etc.

In particular, due to its unique electronic properties, the graphene is expected as a new electronic device material, for example, a material for transistor channel and sensing elements.

Graphene is a two-dimensional crystal and has in-plane anisotropy. In particular, a geometrical structure appearing on an edge of the graphene is roughly divided into two types, i.e., an armchair type and a zigzag type and, with only one of these types or with both regularly or randomly mixed and it is possible to control the characteristics of graphene by controlling the edge structure.

Such edge structure control is important from the viewpoint of application of graphene to electronic devices and attention is being paid to an anisotropic etching technique capable of controlling the edge structure. For example, a technique for anisotropically etching graphene with hydrogen plasma generated by an inductively-coupled remote plasma system has been reported. In this technique, due to a difference in reactivity due to the edge structure, hydrogen radicals in the hydrogen plasma effect etching in which specific direction dominates, thereby resulting in anisotropic etching.

However, with the application of this conventional technique, since the etching proceeds at an atomic level starting from the edge of graphene, there is a problem that an etching rate is as low as several nm/min. Although the etching rate may increase by etching using oxygen-containing plasma, the etching becomes isotropic, which makes it difficult to achieve the desired anisotropic etching. In addition, the oxygen-containing plasma may cause damage to the graphene.

### SUMMARY

Some embodiments of the present disclosure provide a technique capable of anisotropically etching graphene at a high speed.

According to one embodiment of the present disclosure, there is provided a method for anisotropically etching graphene including generating hydrogen plasma by microwave plasma, and anisotropically etching graphene by the generated hydrogen plasma.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view showing an edge structure of graphene.

FIG. 2 is a sectional view schematically showing a workpiece to be subjected to anisotropic etching of graphene.

FIG. 3 is a sectional view schematically showing a state in which anisotropic etching of graphene is performed on the workpiece of FIG. 2.

FIG. 4 is a view for explaining an edge structure when anisotropic etching of graphene is performed.

FIG. 5 is a sectional view showing an example of a microwave plasma treatment apparatus suitable for anisotropic etching of graphene of the present disclosure.

FIG. 6 is a view showing a topographic image taken by AFM and the height of a portion thereof in an experimental example in which graphene is etched by hydrogen plasma generated using the microwave plasma treatment apparatus of FIG. 5.

FIG. 7 is a view showing topographic images taken by AFM at different temperatures in an experimental example in which graphene is etched by hydrogen plasma generated using the microwave plasma treatment apparatus of FIG. 5 while changing temperature.

FIG. 8 is a view showing the relationship between temperature and etching length in an experimental example in which graphene is etched by hydrogen plasma generated using the microwave plasma treatment apparatus of FIG. 5 while changing temperature.

FIG. 9 is a view showing the relationship between temperature and etching rate in an experimental example in which graphene is etched by hydrogen plasma generated using the microwave plasma treatment apparatus of FIG. 5 while changing temperature.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings.

### <Outline of Anisotropic Etching of Graphene>

First, an outline of anisotropic etching of graphene will be described.

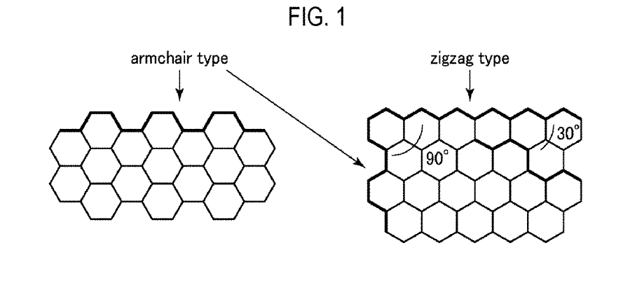

FIG. 1 is a schematic diagram showing an edge structure of graphene.

As described earlier, graphene is a two-dimensional crystal and has in-plane anisotropy. A geometrical structure appearing at an edge of the graphene is roughly divided into two types, i.e., an armchair type (transpolyacetylene-like structure) and a zigzag type (cispolyacetylene-like structure) shown in FIG. 1. The edge is formed in a state in which only one of these types is used or in a state in which both types are regularly or randomly mixed.

The properties of graphene are determined by the edge structure so that the graphene has semi-conductive property in the armchair type, metallic property in the zigzag type, and an intermediate state in the mixture of these types.

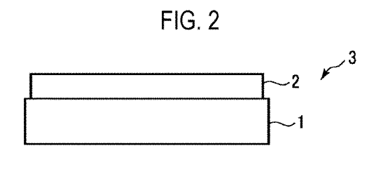

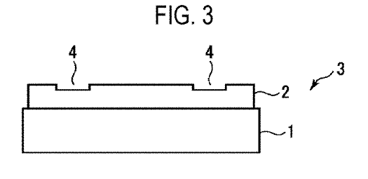

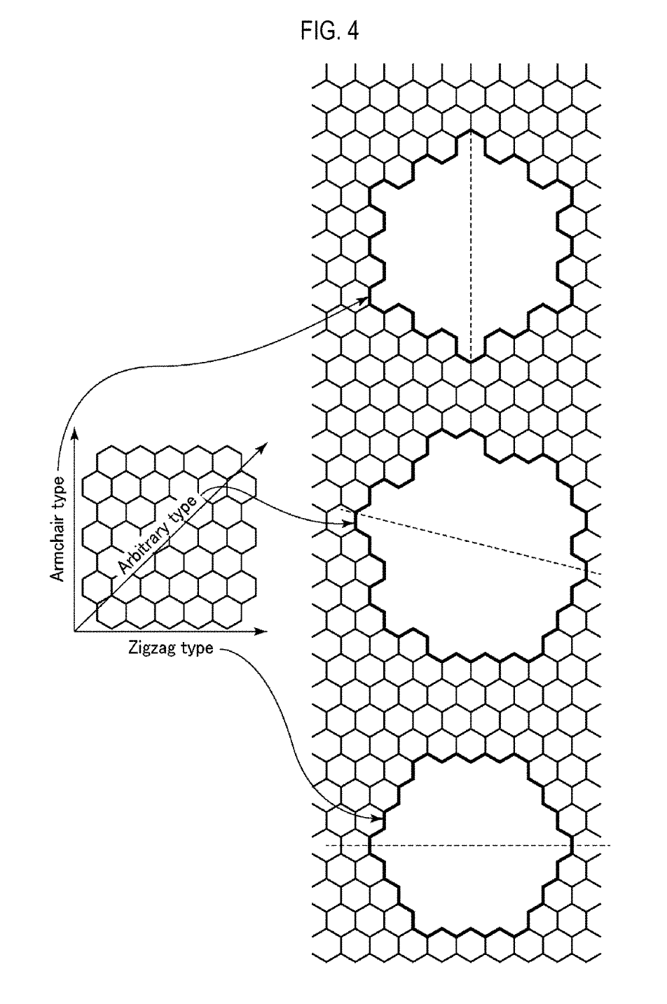

In anisotropic etching, hydrogen plasma treatment is performed on a workpiece 3 including a substrate 1 and a graphene layer 2 formed on the substrate 1 by CVD or the like in a form of single-layered graphene or multi-layered graphene, as shown in FIG. 2. As a result, reactive carbon is hydrogenated and volatilized by hydrogen radicals from defective portions present on the surface of the graphene layer 2, and the etching progresses in a planar shape to form concave portions 4 on the graphene layer 2, as shown in FIG. 3. At that time, a specific crystal plane which can be easily etched under the etching conditions in that moment is preferentially etched so that the edge structure takes one of a zigzag type, an armchair type and an arbitrary type which is a mixture of the zigzag type and armchair type, as shown in FIG. 4. In either case, the edge structure has substantially a regular hexagonal shape and is etched into a planar shape. The regular hexagonal etching region spreads two-dimensionally (in a planar shape) with time in a specific direction corresponding to the crystal plane which is preferentially etched while maintaining the state of the regular hexagon, thereby forming the hexagonal concave portions 4 having a predetermined size on the graphene layer 2, as shown in FIG. 3.

In a case of etching with a predetermined pattern, an appropriate means necessary for patterning, such as an etching mask, is used.

The substrate 1 is not particularly limited but may be made of a metal, a semiconductor or an insulator, and may be crystalline or amorphous. For example, a substrate in which a SiO₂ film is formed on a semiconductor Si may be suitably used.

### <Anisotropic Etching of Graphene by Microwave Plasma>

As described above, the anisotropic etching using hydrogen radicals can be performed by hydrogen plasma generated using an inductively-coupled remote plasma system, but there is the problem with the etching rate being as slow as several nm/min.

In contrast, the present inventors have found that, when hydrogen plasma is generated by a microwave plasma treatment apparatus for generating plasma by emitting a microwave into a processing container for performing an etching process and graphene etching is performed by the hydrogen plasma, an extremely high etching rate of several hundred nm/min higher by two orders than the etching rate by inductively-coupled remote plasma, which is unexpected from the conventional knowledge, can be obtained.

It is assumed that such an extremely high etching rate can be achieved since the microwave plasma is plasma with low electron temperature and high density, and enables high density of hydrogen radicals.

The microwave plasma treatment apparatus is not particularly limited, but it is preferably of a type which radiates a microwave propagated through a waveguide from slots formed in a planar slot antenna.

### <Example of Microwave Plasma Treatment Apparatus>

Next, a microwave plasma treatment apparatus suitable for the anisotropic etching of graphene and having a planar slot antenna will be described.

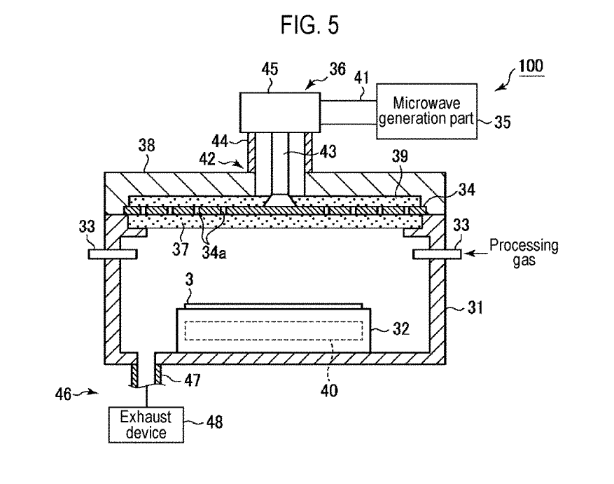

FIG. 5 is a sectional view showing a microwave plasma treatment apparatus suitable for anisotropic etching of graphene. The microwave plasma treatment apparatus 100 includes a cylindrical processing container 31, a mounting table 32 disposed in the processing container 31 and mounting thereon a workpiece, a gas introduction part 33 which is disposed on the side wall of the processing container 31 for introducing a processing gas, a planar slot antenna 34 which is disposed so as to face an opening at the top of the processing container 31 and has slots 34a formed to transmit a microwave, a microwave generation part 35 which generates a microwave, a microwave transmission mechanism 36 which guides the microwave generated from the microwave generation part 35 to the planar slot antenna 34, a microwave-transmitting plate 37 which is disposed on the lower surface of the planar slot antenna 34 and is made of a dielectric material, and an exhaust part 46.

A shield member 38 having a water cooling structure is disposed on the planar slot antenna 34 and a retardation member 39 made of a dielectric material is interposed between the shield member 38 and the planar slot antenna 34.

The planar slot antenna 34 is composed of, for example, a copper plate or an aluminum plate whose surface is plated with silver or gold, and has a plurality of slots 34a for radiating microwaves, formed through the planar slot antenna 34 with a predetermined pattern. The pattern of the slots 34a is appropriately set so that the microwaves are uniformly radiated. An example of the appropriate pattern is a radial line slot in which a plurality of pairs of slots 34a is concentrically arranged, with each pair composed of two slots 34a paired in a T-shape. The length of each slot 34a and the array spacing between the slots 34a are appropriately determined depending on the effective wavelength (λg) of a microwave. The slots 34a may have any other shape such as a circular shape, an arc shape, etc. The shape of the arrangement of the slots 34a is not particularly limited. For example, the slots 34a may be arranged spirally or radially other than concentrically. The pattern of the slots 34a is appropriately set so as to provide the microwave radiation characteristics for obtaining a desired plasma density distribution.

The retardation member 39 is disposed on the upper surface of the planar slot antenna 34. The retardation member 39 is made of a dielectric material having a larger dielectric constant than vacuum, for example, quartz, ceramics (Al₂O₃), resin such as polytetrafluoroethylene or polyimide, etc. The retardation member 39 has a function of making the wavelength of the microwave shorter than that in a vacuum, thereby making the planar slot antenna 34 smaller.

The thicknesses of the microwave-transmitting plate 37 and the retardation member 39 are adjusted so that an equivalent circuit formed by the retardation member 39, the planar slot antenna 34, the microwave-transmitting plate 37 and plasma meets the resonance conditions. By adjusting the thickness of the retardation member 39, the phase of the microwave can be adjusted. Further, by adjusting the thickness of the retardation member 39 so that the junction of the planar slot antenna 34 becomes the belly (i.e., the maximum amplitude point) of a standing wave, the reflection of the microwave is minimized and the radiant energy of the microwave is maximized. In addition, the interfacial reflection of the microwave can be prevented when the retardation member 39 and the microwave-transmitting plate 37 are made of the same material.

The gas introduction part 33 is for introducing a plasma generation gas and a H₂ gas into the processing container 31. A gas supply pipe (not shown) is connected to the gas introduction part 33 and a gas supply source (not shown) for supplying the plasma generation gas and the H₂ gas is connected to the gas supply pipe. Then, these gases are supplied from the gas supply source into the gas introduction part 33 via the gas supply pipe and are introduced from the gas introduction part 33 into the processing container 31. As the plasma generation gas, a rare gas such as Ar, Kr, Xe, He or the like is used. Among these, the Ar gas is particularly suitable. Note that the plasma generation gas is not indispensable and that it is possible to only use the H₂ gas.

The microwave transmission mechanism 36 includes a waveguide 41 extending in the horizontal direction for guiding the microwave from the microwave generation part 35, a coaxial waveguide 42 extending upward from the planar slot antenna 34 and including an inner conductor 43 and an outer conductor 44, and a mode conversion mechanism 45 interposed between the waveguide 41 and the coaxial waveguide 42. The microwave generated by the microwave generation part 35 propagates through the waveguide 41 in a TE mode, is then converted to a TEM mode in the mode conversion mechanism 45. The microwave in the TEM mode is guided to the retardation member 39 through the coaxial waveguide 42 and is radiated from the retardation member 39 into the processing container 31 through the slots 34a of the planar slot antenna 34 and the microwave-transmitting plate 37. The frequency of the microwave can be in a range of 300 MHz to 10 GHz, for example, at 2.45 GHz.

The exhaust part 46 includes an exhaust pipe 47 connected to the bottom of the processing container 31 and an exhaust device 48 including a vacuum pump and a pressure control valve. The interior of the processing container 31 is exhausted by the vacuum pump of the exhaust device 48 through the exhaust pipe 47. The pressure control valve is disposed in the exhaust pipe 47 and the internal pressure of the processing container 31 is controlled by the pressure control valve.

The mounting table 32 is provided with a temperature control mechanism 40 capable of adjusting the temperature of a workpiece 3 on the mounting table 32 to a predetermined temperature from room temperature to 800 degrees C., for example.

The side wall of the processing container 31 has a loading/unloading port (not shown) for loading/unloading the workpiece 3 into/from a transfer chamber adjacent to the processing container 31. The loading/unloading port is opened and closed by a gate valve (not shown).

### <Etching Method by Microwave Plasma Treatment Apparatus>

In performing the anisotropic etching of graphene with the microwave plasma treatment apparatus 100 configured as described above, first, the workpiece 3 having the graphene layer 2 is loaded into the processing container 31 and is mounted on the mounting table 32. Then, the internal pressure of the processing container 31 is controlled to a predetermined value and the workpiece 3 heated to a predetermined temperature by the temperature control mechanism is subjected to surface treatment by a H₂ gas. In addition to the H₂ gas, a rare gas such as an Ar gas or the like may be used. This process is a process for removing particles and dust from the surface of the workpiece 5 for purification. This surface treatment is not indispensable.

The conditions for this surface treatment are preferably as follows.

Gas flow rate: Ar/H₂=0 to 2,000/10 to 2,000 sccm

Pressure: 0.1 to 10 Torr (13.3 to 1,333 Pa)

Workpiece temperature: 300 to 600 degrees C.

Time: 10 to 120 min

Subsequently, in a state in which the interior of the processing container 31 is maintained at the same pressure and which the temperature of the workpiece 3 is adjusted to a predetermined temperature, microwave plasma is generated to perform anisotropic etching of graphene while introducing only H₂ gas or a H₂ gas and a rare gas such as an Ar gas, which is a plasma generation gas, into the processing container 31.

In generating the microwave plasma, the microwave generated by the microwave generation part 35 is guided to the retardation member 39 through the waveguide 41, the mode conversion mechanism 45 and the coaxial waveguide 42 of the microwave transmission mechanism 36 and is radiated into the processing container 31 from the retardation member 39 through the slots 34a of the planar slot antenna 34 and the microwave-transmitting plate 37.

The microwave spreads as a surface wave into a region immediately under the microwave-transmitting plate 37 to generate surface wave plasma. Then, the surface wave plasma spreads downward, thereby providing plasma having a high hydrogen radical density and a low electron temperature in the arrangement region of the workpiece 3.

By using such microwave plasma, it is possible to anisotropically etch the graphene layer 2 of the workpiece 3 at a high etching rate.

The conditions for the hydrogen plasma treatment by the microwave plasma are preferably as follows.

Gas flow rate: Ar/H₂=0 to 2,000/10 to 2,000 sccm

Pressure: 0.1 to 10 Torr (13.3 to 1,333 Pa)

Workpiece temperature: room temperature to 800 degrees C.

Microwave power: 0.5 to 5 kW

At this time, the etching rate of graphene greatly varies depending on the temperature, which is preferably 400 degrees C. or more, more preferably 450 degrees C. or more. The etching rate is 80 nm/min at 400 degrees C. and 290 nm/min at 470 degrees C., which are extremely large values.

As described above, according to the present embodiment, it is possible to perform anisotropic etching of graphene at a very high etching rate compared to a conventional technique utilizing hydrogen plasma etching using microwave plasma.

It is thought that it is possible to control the edge structure of graphene by adjusting the processing conditions by using this method. In addition, there is a possibility that various devices such as transistor channels, sensing elements, wirings, etc. can be realized using graphene, with a practical throughput by way of using a high etching rate.

### Experimental Example

Next, an experiment example will be described.

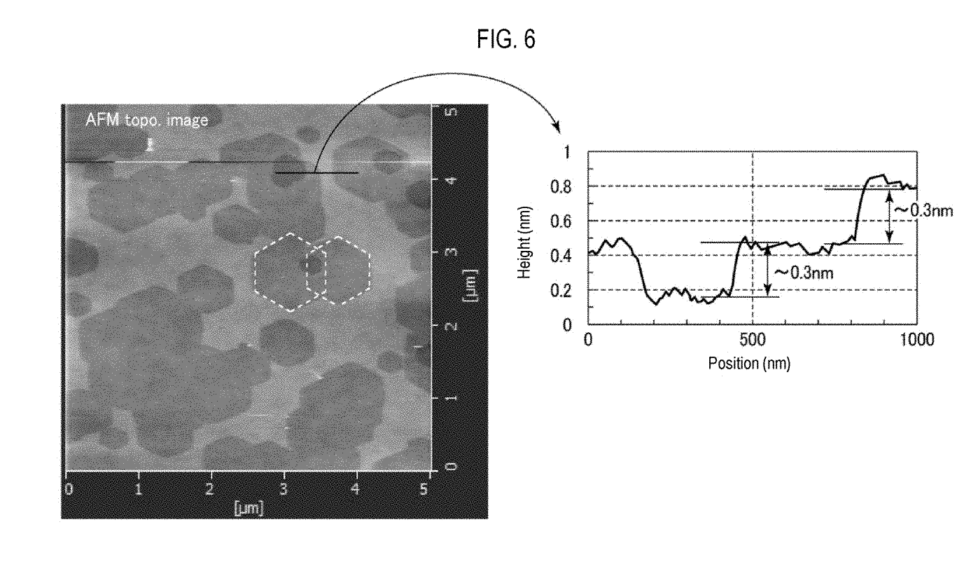

Here, the microwave plasma treatment apparatus shown in FIG. 5 was used to perform etching of graphene by hydrogen plasma under the conditions of gas flow rate: Ar gas=500 sccm and H₂ gas=500 sccm, pressure: 3 Torr, temperature: 400 degrees C., microwave power: 1 kW and time: 8 min. FIG. 6 is a view showing a topographic image taken by AFM (Atomic Force Microscope) at that time and the height of a portion thereof. In the topographic image, a darker color indicates a lower height. As shown in this figure, regular hexagonal concave portions were confirmed and it was confirmed that a graphene single layer with a thickness of approximately 0.3 nm was anisotropically etched.

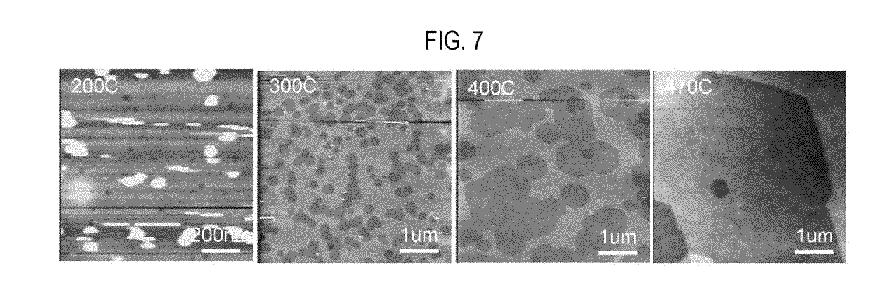

Next, similarly, the microwave plasma treatment apparatus shown in FIG. 5 was used to perform etching of graphene by hydrogen plasma under the conditions of gas flow rate: Ar gas=500 sccm and H₂ gas=500 sccm, pressure: 3 Torr, microwave power 1 kW and time: 8 min, while changing temperature to 200 degrees C., 300 degrees C., 400 degrees C. and 470 degrees C. FIG. 7 is a view showing topographic images taken by AFM at that time. As shown in FIG. 7, it can be seen that an anisotropically-etched regular hexagonal portion spreads rapidly with the increase in temperature.

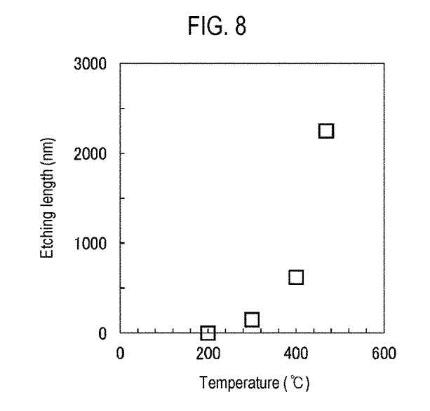

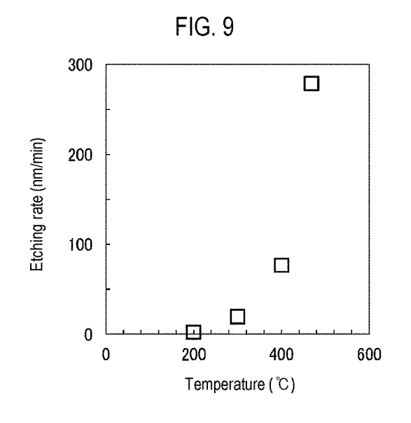

FIG. 8 shows an etching length (the length from the center of the regular hexagon which is the etched portion to the midpoint of one side) at each temperature. It can be seen from FIG. 8 that the anisotropic etching length of graphene rapidly increases from 400 degrees C. An etching rate was obtained by dividing the etching length by a processing time (8 min). The results are shown in FIG. 9. It can be seen from FIG. 9 that an etching rate of several nm/min at 200 degrees C. and several tens of nm/min at 300 degrees C. significantly increases to 80 nm/min at 400 degrees C. and 290 nm/min at 470 degrees C., which are higher by about two orders than an etching rate of anisotropic etching of several nm/min with the maximum of 6 nm/min using hydrogen plasma in the inductively-coupled remote plasma system of the conventional technique.

### Other Applications

Although the embodiments of the present disclosure have been described above, the present disclosure is not limited to the above-described embodiments but various modifications can be made without departing from the spirit and scope of the present disclosure. For example, the microwave plasma treatment apparatus used in the above embodiments is just illustrative but may be of different types.

Further, a substrate on which graphene to be etched is formed is not particularly limited as described above but an appropriate substrate may be used according to its usage and applications.

According to the present disclosure in some embodiments, it is possible to anisotropically etch graphene at a high speed by using hydrogen plasma generated by microwave plasma.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for anisotropically etching graphene, comprising:
generating hydrogen plasma by microwave plasma; and
anisotropically etching graphene by the generated hydrogen plasma.

2. The method of claim 1, wherein, in a state where a workpiece having a substrate and the graphene formed on the substrate is accommodated in a processing container, the generating hydrogen plasma by microwave plasma comprises radiating a microwave into the processing container while supplying a processing gas into the processing container.

3. The method of claim 2, further comprising guiding the microwave from a microwave generation part to a planar slot antenna and radiating the microwave from slots formed in the planar slot antenna to have a predetermined pattern into the processing container.

4. The method of claim 3, wherein the planar slot antenna is a planar slot antenna with a radial line slot.

5. The method of claim 2, wherein the processing gas contains only a hydrogen gas, or a hydrogen gas and a rare gas.

6. The method of claim 1, wherein a temperature at which the graphene is anisotropically etched is equal to or higher than 400 degrees C.

7. The method of claim 6, wherein the temperature at which the graphene is anisotropically etched is equal to or higher than 450 degrees C.

8. The method of claim 1, further comprising: prior to the anisotropically etching graphene by the hydrogen plasma, performing a surface treatment to the graphene by a processing gas including a hydrogen gas.

9. The method of claim 8, wherein a temperature during the surface treatment is in a range of 300 to 600 degrees C.
